(19) United States
(12) Patent Application Publication
(10) Pub. No.: US 2022/0290049 A1
(43) Pub. Date: Sep. 15, 2022

(54) COMPOSITION OF ETCHANT, METHOD FOR FORMING SEMICONDUCTOR DEVICE USING THE SAME, AND SEMICONDUCTOR DEVICE

(71) Applicant: LCY CHEMICAL CORP., Kaohsiung City (TW)

(72) Inventors: Shang-Chen HUANG, Kaohsiung City (TW); Cheng-Huan HSIEH, Kaohsiung City (TW)

(21) Appl. No.: 17/691,453

(22) Filed: Mar. 10, 2022

Related U.S. Application Data
(60) Provisional application No. 63/160,243, filed on Mar. 12, 2021.

(51) Int. Cl. C09K 13/00; H01L 21/28; H01L 21/3213; H01L 29/66

(52) U.S. Cl. CPC C09K 13/00; H01L 21/28132; H01L 21/32134; H01L 29/66545

(57) ABSTRACT

The composition of an etchant is provided. The composition of the etchant includes about 0.1 to 13 wt % quaternary ammonium salt and about 45 to 90 wt % aprotic organic solvent. A method for forming a semiconductor device is provided. The method for forming the semiconductor device includes a step of removing a dummy gate by using an etchant with a composition that includes about 0.1 to 13 wt % quaternary ammonium salt and about 45 to 90 wt % aprotic organic solvent. A semiconductor device is provided. The semiconductor device includes a polycrystalline silicon component having an etched surface that was etched by an etchant with a composition that includes about 0.1 to 13 wt % quaternary ammonium salt and about 45 to 90 wt % aprotic organic solvent. The surface arithmetic mean height of the etched surface is 20 nm or less.

### CROSS REFERENCE TO RELATED APPLICATIONS

This application claims the benefit of U.S. Provisional Application No. 63/160,243, filed Mar. 12, 2021, the entirety of which is incorporated by reference herein.

### BACKGROUND OF THE INVENTION

### Field of the Invention

The technical field relates to a composition of an etchant, a method for forming a semiconductor device using the same, and a semiconductor device.

### Description of the Related Art

As the size of transistors continues to shrink, High-k Metal Gate (HKMG) technology has almost become a necessary technology for process technology of 45 nm and smaller. The HKMG process can be classified into a gate-first process and a gate-last process, depending on when metal gates are formed.

The gate-last process includes a step of forming a dummy gate, a step of performing an ion implantation and a high-temperature annealing, a step of removing the dummy gate, and a step of forming a metal gate. In the gate-last process, the metal gate is formed after the step of performing the high-temperature annealing. Therefore, compared to the gate-first process, poor performance and instability of the transistors caused by high-temperature annealing can be avoided in the gate-last process.

The dummy gate may include polysilicon (poly-Si). The polysilicon may include different crystalline surfaces, such as silicon <100> surfaces, silicon <110> surfaces, and silicon <111> surfaces. Conventional etchant compositions used to remove the dummy gate have different etching rates on different crystalline surfaces of the polysilicon, which can lead to polysilicon residue, resulting in a loss of yield and electrical degradation of subsequently formed electronic devices.

Therefore, there is still an urgent need for the industry to develop an etchant with a composition that makes it suitable for use in the HKMG process.

### BRIEF SUMMARY OF THE INVENTION

An aspect of the present disclosure provides a composition of an etchant comprising 0.1 to 13 wt % of quaternary ammonium salts and 45 to 90 wt % of polar aprotic solvent.

Another aspect of the present disclosure provides a method for forming a semiconductor device. The method comprises forming an insulation layer over a substrate; forming a dummy gate over the insulation layer; forming a spacer on both sides of the dummy gate and the insulation layer; removing the dummy gate to form a groove; and forming a metal gate in the groove. The step of removing the dummy gate comprises using a composition of an etchant comprising 0.1 to 13 wt % of quaternary ammonium salts and 45 to 90 wt % of polar aprotic solvent.

Another aspect of the present disclosure provides a semiconductor device comprising a polysilicon element having an etched surface. The etched surface is formed by a wet etching process and has a surface arithmetic mean height of 20 nm or less. The wet etching process comprises using a composition of an etchant, the composition of the etchant comprising 0.1 to 13 wt % of quaternary ammonium salts and 45 to 90 wt % of polar aprotic solvent.

### BRIEF DESCRIPTION OF THE DRAWINGS

The present invention can be more fully understood by reading the subsequent detailed description and examples with references made to the accompanying drawings, wherein:

FIG. 1 is a flowchart illustrating a method for forming a semiconductor device according to an embodiment of the present disclosure.

### DETAILED DESCRIPTION OF THE INVENTION

It will be further understood that the terms “comprises,” “comprising,” “includes” and/or “including,” when used herein, specify the presence of stated features, integers, steps, operations, elements, components and/or groups thereof, but do not preclude the presence or addition of one or more other features, integers, steps, operations, elements, components and/or groups thereof. As used herein, the singular forms “a,” “an” and “the” are intended to include the plural forms as well, unless the context clearly indicates otherwise.

It will be understood that, although the terms first, second, etc. are be used herein to describe various elements, components, regions, layers and/or portions, these elements, components, regions, layers and/or portions should not be limited by these terms. These terms are used to distinguish one elements, components, regions, layers or portions from another elements, components, regions, layers or portions, but not to imply a required sequence of elements. For example, a first element can be termed a second element, and, similarly, a second element can be termed a first element.

It will be understood that, the term “about”, “approximate”, “rough” as used herein usually indicates a value of a given value or range that varies within 20%, preferably within 10%, and preferably within 5%, or within 3%, or within 2%, or within 1%, or within 0.5%. The value given here are approximate value, i.e., “about”, “approximate”, or “rough” may be implied without specifying “about”, “approximate”, or “rough”. It will be further understood that the values indicated in herein may include the said values as well as deviation values that are within an acceptable deviation range for people having general knowledge in art. For example, taking into account the measurement error (i.e., limitation or measurement error of the measurement system, or limitation or process error of the process system) for the etching rate of polysilicon and SiO₂, the etching rate of polysilicon may contain ±50 Å/min of the stated value and the etching rate of SiO₂ may contain ±0.05 Å/min of the stated value. Taking into account the formulation error of the composition, the content of each component of the composition may contain ±5% of the stated value.

It will be understood that the expression “a-b” used herein to indicate a specific range of values is defined as “≥a and ≤b”.

Unless otherwise defined, all terms (including technical and scientific terms) used herein have the same meaning as commonly understood by a person skilled in the art to which the invention pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein. Descriptions of known functions and constructions that may unnecessarily obscure the present disclosure will be omitted below.

The present disclosure provides a composition of an etchant comprising a quaternary ammonium salt and a polar aprotic solvent.

Quaternary ammonium salts inhibit or retard etching of silicon oxides, silicon nitrides, silicon carbides, and silicon carbide nitrides, but provide good etching rates for polycrystalline silicon layers, monocrystalline silicon layers, or amorphous silicon layers. In other words, the quaternary ammonium salts improves the composition of the etchant in the etch selectivity ratio of silicon materials to silicon oxides, silicon nitrides, silicon carbides, and/or silicon carbide nitride.

In some embodiments, the quaternary ammonium salts may have the structure shown in formula (I) below:

N(R¹)₄⁺X (I)

wherein, R¹ may each be independently selected from the group consisting of a substituted or unsubstituted alkyl group, a substituted or unsubstituted aryl group, and combinations thereof, and each R¹ may be the same as or different from each other. X⁻ may be selected from the group consisting of F, Cl⁻, Br⁻, I⁻, HsO₄⁻, RCOO⁻, and OH⁻.

In some embodiments, R¹ may each be independently selected from the group consisting of a substituted or unsubstituted C₁-C₂₀ alkyl group, a substituted or unsubstituted C₆-C₂₀ aryl group, and combinations thereof. In some embodiments, R¹ may each be independently selected from a substituted or unsubstituted C₁-C₆ alkyl group. In some embodiments, R¹ may each be independently selected from the group consisting of a methyl group, an ethyl group, a propyl group, a butyl group, an isobutyl group, a sec-butyl group, a tert-butyl group, a pentyl group, an isoamyl group, and a hexyl group.

The term “C₁-C₂₀ alkyl group” or “unsubstituted C₁-C₂₀ alkyl group” used herein refers to a straight or branched aliphatic hydrocarbon monovalent group having 1 to 20 carbon atoms in the main carbon chain thereof. Non-limiting examples of the C₁-C₂₀ alkyl group or the unsubstituted C₁-C₂₀ alkyl group comprise, but not limited to, a methyl group, an ethyl group, a propyl group, an isobutyl group, a sec-butyl group, a tert-butyl group, a pentyl group, an isoamyl group, and a hexyl group. The term “substituted C₁-C₂₀ alkyl group” used herein refers to a monovalent group that at least one hydrogen atom on the C₁-C₂₀ alkyl group or the unsubstituted C₁-C₂₀ alkyl group is substituted with OH, O, N, S, deuterium, tritium, halogen, amine, C₁-C₆ alkyl group. The terms “C₁-C₆ alkyl group”, “unsubstituted C₁-C₆ alkyl group”, or “substituted C₁-C₆ alkyl group” are used herein in a similar manner and are not repeated herein. The terms “C₁-C₆ alkyl group”, “unsubstituted C₁-C₆ alkyl group”, or “substituted C₁-C₆ alkyl group” used herein are interpreted in a similar manner and are not repeated herein.

The term “C₆-C₂₀ aryl group” or “unsubstituted C₆-C₂₀ aryl group” used herein refers to a monovalent group having a carbocyclic aromatic system containing 6 to 20 carbon atoms. Non-limiting examples of the C₆-C₂₀ aryl group or the unsubstituted C₆-C₂₀ aryl group include but not limited to a phenyl group, a naphthyl group, an anthracenyl group, and a phenanthrenyl group. The term “substituted C₆-C₂₀ aryl group” used herein refers to a monovalent group that at least one hydrogen atom on the C₆-C₂₀ aryl group or the unsubstituted C₆-C₂₀ aryl group is substituted with OH, O, N, S, deuterium, tritium, halogen, amine, C₁-C₆ alkyl group.

Specific examples of the quaternary ammonium salts may include, but not limited to, tetramethylammonium hydroxide (TMAH), tetraethylammonium hydroxide (TEAH), tetrabutylammonium hydroxide (TBAH), benzyltrimethylammonium hydroxide, triethylmethylammonium hydroxide, 2-hydroxy-hydroxide (TMA), and tetrapropylammonium hydroxide (TPAH). In some embodiments, the quaternary ammonium salt may include tetramethylammonium hydroxide (TMAH), tetraethylammonium hydroxide (TEAH), tetrabutylammonium hydroxide (TBAH), benzyltrimethylammonium hydroxide, triethylmethylammonium hydroxide, 2-hydroxy-hydroxides (TMA), and tetrapropylammonium hydroxide (TPAH), or any combination thereof. In some embodiments, the quaternary ammonium salt may include tetramethylammonium hydroxide (TMAH), tetraethylammonium hydroxide (TEAH), tetrabutylammonium hydroxide (TBAH), triethylmethylammonium hydroxide, tetrapropylammonium hydroxide (TPAH), or any combination thereof. In some embodiments, the quaternary ammonium salt includes tetramethylammonium hydroxide (TMAH), tetraethylammonium hydroxide (TEAH), or any combination thereof.

Based on the total weight of 100 wt % of the composition of the etchant, the composition of the etchant may include about 0.1 to 13 wt % of the quaternary ammonium salts. In some embodiments, the composition of etchant may include about 0.1 to 10 wt %, about 0.1 to 8 wt %, about 0.1 to 5 wt %, about 0.1 to 3 wt %, about 2 to 3 wt %, about 12.5 wt %, about 3.71 wt %, about 2.38 wt %, about 2.36 wt %, about 1.9 wt %, about 1.6 wt %, about 1.0 wt %, about 0.8 wt %, about 0.7 wt %, about 0.5 wt %, or about 0.3 wt % of the quaternary ammonium salts. If the quaternary ammonium salt content in the composition of the etchant is too high, e.g. more than 13 wt %, the composition of the etchant may be delaminated and cannot be used in a wet etching process. If the quaternary ammonium salt content in the composition of the etchant is too low, e.g. less than 0.1 wt %, the composition of the etchant may not provide a good etching rate for polysilicon, monocrystalline silicon or amorphous silicon layers. In the case that the quaternary ammonium salt content in the composition of the etchant is in the range described above, the composition of the etchant disclosed herein may provide good etching rates for the polysilicon, monocrystalline silicon or amorphous silicon layers while reducing or decreasing etching of silicon oxides, silicon nitrides, silicon carbides and/or silicon carbide, improving the etch selectivity ratio of silicon materials to the silicon oxides, the silicon nitrides, the silicon carbides and/or the silicon carbide.

The polar aprotic solvent is an organic aprotic solvent with high polarity. In some embodiments, the polar aprotic solvent is a aprotic solvent having a dielectric constant greater than 15 (measured at 1 KHz, 25° C.). Examples of the polar aprotic solvent may include, but not limited to, sulfoxide solvents, such as dimethyl sulfoxide (DMSO); sulfone solvents, such as sulfolane (SFL); ester solvents, such as propylene glycol methyl ether acetate (PGMEA), γ-butyrolactone (GBL); amide solvents, such as dimethylformamide (DMF), dimethylacetamide (DMAC); ketone solvents, such as N-methylpyrrolidone (NMP), N-ethyl-2-pyrrolidone (NEP); ether solvents, such as diethylene glycol dimethyl ether, diethylene glycol diethyl ether (DEGDEE), propylene glycol methyl ether (PGME), butyl diglycol (BDG); furan solvents, such as tetrahydrofuran (THF); and combinations thereof. In some embodiments, the polar aprotic solvent may be sulfone solvents, sulfoxide solvents, or any combinations thereof. In further embodiments, the polar aprotic solvent may be sulfone solvents. In some embodiments, the polar aprotic solvent may be sulfolane, dimethyl sulfoxide, or a combination thereof.

Based on the total weight of 100 wt % of the composition of the etchant, the composition of the etchant may include about 45 to 90 wt % of the polar aprotic solvent. In some embodiments, the composition of the etchant may include about 50 to 85 wt %, about 55 to 80 wt %, about 60 to 75 wt %, about 70 to 75 wt %, about 81.43 wt %, about 79.85 wt %, about 75 wt %, about 70 wt %, about 69.3 wt %, or about 59.45 wt %, or about 50 wt % of the polar aprotic solvent. If the polar aprotic solvent content in the composition of the etchant is too high, e.g. more than 90 wt %, the quaternary ammonium salt content in the composition of the etchant may be too low. Therefore, the composition of the etchant may not provide a good etching rate for the polysilicon, monocrystalline silicon or amorphous silicon layers. If the polar aprotic solvent content in the composition of the etchant is too low, e.g. less than 45 wt %, the composition of the etchant may not etch different crystalline surfaces of polysilicon at similar etching rates and may result in a rough etched surface and/or residual polysilicon. In cases where the polar aprotic solvent content in the composition of the etchant is in the range described above, the composition of the etchant may etch different crystalline surfaces of polysilicon at similar etching rates and may result in an etched surface with a smaller surface arithmetic mean height and/or an etched surfaces with less polysilicon residue.

The term “surface arithmetic mean height” used herein refers to an arithmetic mean of distances between points on a surface profile and a base surface. In other words, the surface arithmetic mean height Sa of a sampling area is an arithmetic mean of distances in a z-axis between a measured profile surface and a datum plane in the sampling area, wherein a xy-plane is used as the datum plane. That is, an arithmetic mean of the absolute values of z-axis in a surface roughness surface equation. The larger the surface arithmetic mean height indicates the rougher the surface. The surface arithmetic mean height conforms to the following equation, wherein A indicates the area of the sampling area:

$$Sa = \frac{1}{A} \int {\int }_{A} \vert Z ( x , y ) \vert dxdy$$

In some embodiments, the composition of the etchant may include a polar protic solvent for further reducing the surface arithmetic mean height of the etched surface and/or increasing the etch selectivity ratio of silicon materials to the silicon oxides, the silicon nitrides, the silicon carbides, and/or the silicon carbide nitride. Examples of the polar protic solvent may include, but not limited to, ester solvents, such as ethylene carbonate (EC); alcohol solvents; and combinations thereof. The alcohol solvents may include alkyl alcohol solvents, such as ethylene glycol (EG), 1,2-propanediol, 1,3-propanediol (PG), glycerol (G1), 1,4-butanediol (BDO), pentaerythritol (PENTA), 1,6-hexanediol (1,6-HDO); ether solvents, such as di-pentaerythritol (DiPE); aromatic alcohol solvents, such as benzenediol; or any combinations thereof. In some embodiments, the polar protic solvent may be alcohol solvents, ether solvents, or a combination thereof. In some embodiments, the alcohol solvents may be a polyol compound. In further embodiments, the polar protic solvent may be alkyl alcohol solvents. In further embodiments, the polar protic solvent may be a C₂-C₁₅ alkyl alcohol solvent. In further embodiments, the polar protic solvent may be an alkyl alcohol solvent. In further embodiments, the polar protic solvent may be a C₂-C₁₀ alkyl alcohol solvent.

The term “C₂-C₁₅ alkyl alcohol solvent” used herein includes C₂-C₁₅ alkyl alcohol compounds. The term “C₂-C₁₅ alkyl alcohol solvent” used herein refers to a compound, which is at least one hydrogen atom on a straight or branched aliphatic hydrocarbon compound having 2 to 15 carbon atoms in the main carbon chain is substituted with OH.

Based on the total weight of 100 wt % of the composition of the etchant, the composition of the etchant may include about 0.1 to 50 wt % of the polar protic solvent. In some embodiments, the composition of the etchant may include about 0.1 to 25 wt %, 0.1 to 30 wt %, about 1 to 30 wt %, about 5 to 11 wt %, about 5 to 20 wt %, about 6 to 15 wt %, about 10.69 wt %, or about 10 wt % of the polar protic solvent. If the polar protic solvent content in the composition of the etchant is too high, e.g. more than 50 wt %, the polar aprotic solvent content in the composition of the etchant may be too low. In this case, the etchant may not etch different crystalline surfaces of polysilicon at similar etching rates and may result in a rough etched surface and/or residual polysilicon. In cases where the polar protic solvent content in the composition of the etchant is in the range described above, an etched surface with a smaller surface arithmetic mean height can be obtained by using the etchant with the composition of the present disclosure.

In some embodiments, Based on the total weight of 100 wt % of the composition of the etchant, the sum of the polar protic solvent and the polar aprotic solvent accounts for about 50 to 93 wt % of the composition of the etchant. In some embodiments, the sum of the polar protic solvent and the polar aprotic solvent accounts for about 50 to 90 wt %, about 55 to 90 wt %, about 78 to 85 wt %, about 80 to 93 wt %, or about 80 to 90 wt % of the composition of the etchant. In cases where the polar protic solvent content and the polar aprotic solvent content in the composition of the etchant are in the range described above, an etched surface with a smaller surface arithmetic mean height can be obtained by using an etchant with the composition of the present disclosure.

In some embodiments, the composition of the etchant may include a surfactant for further enhancing the etch selectivity ratio of silicon materials to the silicon oxide, the silicon nitride, the silicon carbide, and/or the silicon carbide nitride. The surfactant may include, but not limited to, fluorinated anion surfactant, fluorinated nonionic surfactant, fluorinated amphoteric surfactant, hydrocarbon anion surfactant, and combinations thereof. Specific examples of the surfactant may include, but not limited to, Surfynol SE (purchased from EVONIK), Surfynol AD-01 (purchased from EVONIK), Enoric BS-24 (purchased from HAMS Universal), Dynol 604 (purchased from EVONIK), Dynol 607 (purchased from EVONIK), FC-4430 (purchased from 3M), or any combinations thereof.

Based on the total weight of 100 wt % of the composition of the etchant, the composition of the etchant may include about 0.01 to 0.5 wt % of the surfactant. In some embodiments, the composition of the etchant may include about 0.03 to 0.45 wt %, about 0.05 to 0.3 wt %, or about 0.28 wt % of the surfactant. If the surfactant content in the composition of the etchant is too high, e.g. more than 0.5 wt %, the surfactant will self-agglomerate to form microcells and lose the function of reducing surface tension, resulting in poor etching results.

In some embodiments, the composition of the etchant does not include metal ions. In some embodiments, Based on the total weight of 100 wt % of the composition of the etchant, the composition of the etchant may include about 5 to 50 wt % of water. In some embodiments, the composition of the etchant may include about 6 to 50 wt %, about 8 to 30 wt %, or about 9 to 20 wt % of water.

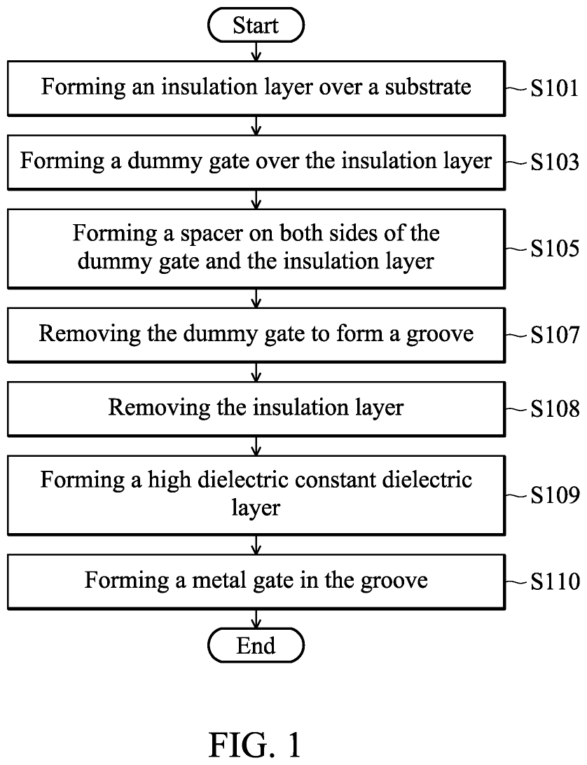

Another aspect of the present disclosure provides a method for forming a semiconductor device. As shown in FIG. 1, the method for forming a semiconductor device comprises a step S101 of forming an insulation layer over a substrate; a step S103 of forming a dummy gate over the insulation layer; a step S105 of forming a spacer on both sides of the dummy gate and the insulation layer; a step S107 of removing the dummy gate to form a groove; and a step S110 of forming a metal gate in the groove.

In the step S101, the term “substrate” may include a base substrate, components formed on the base substrate and various films or layers over the base substrate. A plurality of active elements (transistor elements) and/or passive elements may be formed over the base substrate as desired. The base substrate may be a transparent base substrate. Specific examples of the base substrate may include, but not limited to, glass substrates; sapphire substrates; or semiconductor substrates, such as bulk semiconductor substrates, semiconductor-on-insulator (SOI) substrates, or silicon on insulator substrates. The base substrate may be P-doped, N-doped or un-doped base substrate. The insulation layer may be formed on the substrate by a sputtering method, a physical vapor deposition (PVD) method, a chemical vapor deposition (CVD) method, a plasma chemical vapor deposition (PECVD) method, a vacuum vapor deposition method, a pulsed laser deposition (PLD) method, an metal-organic chemical vapor deposition (MOCVD) method, an atomic layer deposition (ALD) method, a coating method, a printing method, or any of the techniques known in the art. In some embodiments, the insulation layer may be an oxide, such as a silicon oxide.

In the step S103, the dummy gate is formed over the insulation layer formed in the step S101 by a sputtering method, a physical vapor deposition method, a chemical vapor deposition method, a plasma chemical vapor deposition method, a vacuum vapor deposition method, a pulsed laser deposition method, an metal-organic chemical vapor deposition method, an atomic layer deposition method, a coating method, a printing method, or any of the techniques known in the art. The material used to form the dummy gate in the step S103 may be a material having an etch selectivity to the material used to form the insulation layer in step S101. For example, in cases where the insulation layer includes an oxide, the dummy gate may include a polycrystalline silicon, a monocrystalline silicon, an amorphous silicon, or any combinations thereof. In some embodiments, the sides of the dummy gate formed in the step S103 are aligned with the sides of the insulation layer formed in the step S101.

In the step S105, the spacer is formed on the both sides of the dummy gate and the insulation layer by a chemical vapor deposition method, a plasma chemical vapor deposition method, a vacuum vapor deposition method, a pulsed laser deposition method, an metal-organic chemical vapor deposition method, an atomic layer deposition method, a coating method, a printing method, or any of the techniques known in the art. The material used to form the spacer may be a material having an etch selectivity to the material of the dummy gate and the material of the insulation layer. For example, in cases where the insulation layer includes an oxide and the dummy gate include a polycrystalline silicon, a monocrystalline silicon, an amorphous silicon, or any combinations thereof, the spacer may include nitrides, such as silicon nitride, titanium nitride.

The dummy gate is removed to form the groove defined by the spacer in the step S107. In the step S107, the dummy gate is removed by a wet etching method using an etchant with the composition of the present disclosure. The components, proportions and advantages of the composition of the etchant have been described above, so they will not be repeated. Compared to conventional etchant compositions, using an etchant with the composition of the present disclosure to remove the dummy gate may result in a finer etched surface and lower residue of the dummy gate, and the dummy gate may be removed at a good etching rate while maintaining the insulation layer and/or spacer free from being etched. Further, compared to conventional etchant compositions, an etchant with the composition of the present disclosure does not include metal ions and has excellent water solubility. Therefore, the electrical properties of a final semiconductor device being affected by residue of the composition of the etchant and residue of the metal ions in the composition of the etchant can be prevented.

In the step S110, the metal gate is formed in the groove by a chemical vapor deposition method, a plasma chemical vapor deposition method, a vacuum vapor deposition method, a pulsed laser deposition method, an metal-organic chemical vapor deposition method, an atomic layer deposition method, a coating method, a printing method, or any of the techniques known in the art to complete the formation of the semiconductor device. In some embodiments, the metal gates may include titanium (Ti), titanium nitride (TiN), titanium-aluminum (TiAl), aluminum (Al), aluminum nitride (AlN), tantalum (Ta), tantalum nitride (TaN), lanthanum, aluminum titanium oxide (AlTiO), or any combinations thereof.

In some embodiments, the method for forming a semiconductor device may further comprise a step S109 of forming a high dielectric constant dielectric layer (high K dielectric layer). The step S109 may include forming the high dielectric constant dielectric layer on inner walls of the groove and on the substrate in the groove by a chemical vapor deposition method, a plasma chemical vapor deposition method, a vacuum vapor deposition method, a pulsed laser deposition method, an metal-organic chemical vapor deposition method, an atomic layer deposition method, a coating method, a printing method, or any of the techniques known in the art, using a high dielectric constant dielectric material. The step S109 may be performed before the step S110 so that the high dielectric constant dielectric layer is formed between the subsequently formed metal gate and the spacer and/or between the metal gate and the substrate. In some embodiments, the high dielectric constant dielectric material may be a material with a dielectric constant of about 10 or higher. Specific examples of the high dielectric constant dielectric materials may include, but not limited to, tantalum oxide (Ta₂O₅), hafnium oxide (HfO₂), zirconium oxide (ZrO₂), titanium oxide (TiO₂), aluminum oxide (Al₂O₃), hafnium silicate (HfSiOₓ), and any combinations thereof, but the present disclosure is not limited thereto.

In some embodiments, the method for forming a semiconductor device may further comprise a step S108 of removing the insulation layer. In some embodiments, the step S108 may be performed after the step S107 and before the step S109. In some embodiments, in the step S108, the insulation layer may be removed by any etching process known in the art, such as a dry etching process, a wet etching process, or a combination thereof.

In some embodiments, the method for forming a semiconductor device may further comprise performing various processes such as dopant implantation processes, annealing processes, etc., by means well known in the art prior to the step S110. The details of these processes are not repeated herein to avoid obscuring the purpose of the present disclosure.

By including the steps mentioned above, the above-described method for forming a semiconductor device of the present disclosure can provide a semiconductor device with better electrical effects and higher yields while maintaining the speed of the formation of the semiconductor device.

Another aspect of the present disclosure provides a semiconductor device comprising a polysilicon element. The polysilicon element has an etched surface with a surface arithmetic mean height of 20 nm or less. In some embodiments, the etched surface is formed by an etchant with the composition of the present disclosure. The components, proportions and advantages of the composition of the etchant have been described above, so they will not be repeated. Compared to the etched surface formed by the conventional etchant compositions, the etched surface formed by an etchant with the composition of the present disclosure has a smaller surface arithmetic mean height.

Specific embodiments are provided below to further illustrate features and advantages of the present disclosure. However, those skilled in the art should understand that the present disclosure is not limited to the specific embodiments disclosed below.

The compositions of Examples 1 to 26 and Comparative Example were prepared by mixing the following components in the proportions shown in Tables 1 to 6. The values shown in Tables 1 to 6 are the proportions of each component based on a total weight of 100 wt % of the composition.

Quaternary ammonium salts: Tetramethylammonium hydroxide (TMAH), Tetraethylammonium hydroxide (TEAH);
Polar aprotic solvent: Dimethyl sulfoxide (DMSO), Sulfolane (SFL), Ethanolamine (MEA);
Polar protic solvent: Ethylene glycol (EG), 1,3-propanediol (PG), glycerol (G1), 1,4-butanediol (BDO), pentaerythritol (PENTA), 1,6-hexanediol (1,6-HDO), di-pentaerythritol (DiPE);

### Surfactant: Fluorinated Nonionic Surfactant

TABLE 1

| | Example 1 | Example 2 | Example 3 | Example 4 |
|---|---|---|---|---|
| TMAH(wt %) | 0.1 | 0.3 | 0.5 | 0.7 |
| SFL(wt %) | 90 | 90 | 90 | 90 |
| Water(wt %) | 9.9 | 9.7 | 9.5 | 9.3 |

TABLE 2

| | Exam- | Exam- | Exam- | Exam- | Exam- |
|---|---|---|---|---|---|
| | ple 5 | ple 6 | ple 7 | ple 8 | ple 9 |
| TMAH(wt %) | 0.8 | 1.6 | 5 | 8 | 12.5 |
| SFL(wt %) | 50 | 50 | 50 | 50 | 50 |
| Water(wt %) | 49.2 | 48.4 | 45 | 42 | 37.5 |

TABLE 3

| | Exam- | Exam- | Exam- | Exam- | Exam- |
|---|---|---|---|---|---|
| | ple 10 | ple 11 | ple 12 | ple 13 | ple 14 |
| TMAH(wt %) | 2.38 | 2.38 | 2.38 | 0.5 | 2.38 |
| SFL(wt %) | 75 | 75 | 70 | 59.45 | 45 |
| EG(wt %) | 5 | 5 | 10 | 10 | 10 |
| Surfactant(wt %) | — | 0.5 | 0.05 | 0.05 | 0.05 |
| Water(wt %) | 17.62 | 17.12 | 17.57 | 30 | 42.57 |

TABLE 4

| | Exam- | Exam- | Exam- | Exam- |
|---|---|---|---|---|
| | ple 15 | ple 16 | ple 17 | ple 18 |
| TMAH(wt %) | 1.9 | 2.38 | 2.38 | 1.9 |
| SFL(wt %) | 81.43 | 60 | 50 | 81.43 |
| EG(wt %) | 10.69 | 20 | 30 | — |
| Surfactant(wt %) | 0.28 | 0.05 | 0.05 | 0.28 |
| Water(wt %) | 5.7 | 17.57 | 17.57 | 16.39 |

TABLE 5

| | Example 19 | Example 20 | Example 21 | Example 22 | Example 23 | Example 24 |
|---|---|---|---|---|---|---|
| TMAH(wt %) | 2.38 | 2.36 | 2.38 | 2.38 | 2.38 | 2.38 |
| SFL(wt %) | 70 | 69.3 | 70 | 70 | 70 | 70 |
| PG(wt %) | 10 | — | — | — | — | — |
| Gl(wt %) | — | 9.9 | — | — | — | — |
| BDO(wt %) | — | — | 10 | — | — | — |
| PENTA(wt %) | — | — | — | 6 | — | — |
| DiPE(wt %) | — | — | — | — | 1 | — |
| 1,6-HDO(wt %) | — | — | — | — | — | 5 |
| Surfactant(wt %) | 0.05 | 0.05 | 0.05 | 0.05 | 0.05 | 0.05 |
| Water(wt %) | 17.57 | 18.39 | 17.57 | 21.57 | 26.57 | 22.57 |

TABLE 6

| | | | Comparative |
|---|---|---|---|
| | Example 25 | Example 26 | Example |
| TMAH(wt %) | — | 2.38 | 1 |
| TEAH(wt %) | 3.71 | — | — |
| SFL(wt %) | 79.85 | — | — |
| DMSO(wt %) | — | 60 | — |
| MEA(wt %) | — | — | 40 |
| EG(wt %) | — | 20 | 5 |
| Surfactant(wt %) | 0.05 | 0.05 | 0.05 |
| Water(wt %) | 16.39 | 17.57 | 53.95 |

Evaluation of Etching Rate and Etch Selectivity Ratio

The compositions of Examples 1 to 26 were heated to 70° C. Polysilicon wafers were immersed in the above compositions for about 30 seconds to 1 minute and silica wafers were immersed in the above compositions for about 120 minutes. Thickness changes of the polysilicon (poly-Si) wafers and silica (SiO₂) wafers before and after immersion in the above compositions were measured using an ellipsometer (HORIBA Uvisel Plus). Etching rate was obtained by dividing the thickness change of the polysilicon and/or silica wafers before and after etching (soaking) by the etching time. Etch selectivity ratio of poly-Si/SiO₂ is calculated by the etching rate obtained above. Specifically, the etching rates and etch selectivity ratio are obtained from the following equations, respectively, and the results are shown in Tables 7 to 13 below:

$$etching rate = \frac{thickness before etching ( Å ) - thickness after etching ( Å )}{etching time ( min )}$$

$$etch selectivity ratio = \frac{Etching rate of poly \check{G} Si}{Etching rate of {SiO}_{2}}$$

TABLE 7

| | Example 1 | Example 2 | Example 3 | Example 4 |
|---|---|---|---|---|
| Etching rate of | 1100 | 1333 | 1619 | 1970 |
| poly-Si (Å/min) | | | | |
| Etching rate of | 0.057 | 0.13 | 0.35 | 0.49 |
| SiO₂ (Å/min) | | | | |
| Etch selectivity ratio | 19298 | 10253 | 4625 | 4020 |

TABLE 8

| | Exam- | Exam- | Exam- | Exam- | Exam- |
|---|---|---|---|---|---|
| | ple 5 | ple 6 | ple 7 | ple 8 | ple 9 |
| Etching rate of | 1025 | 1222 | 2441 | 2586 | 2396 |
| poly-Si (Å/min) | | | | | |
| Etching rate of | 0.74 | 1.25 | 1.17 | 0.97 | 0.66 |
| SiO₂ (Å/min) | | | | | |
| Etch selectivity ratio | 1385 | 977 | 2086 | 2665 | 3630 |

TABLE 9

| | Exam- | Exam- | Exam- | Exam- | Exam- |
|---|---|---|---|---|---|
| | ple 10 | ple 11 | ple 12 | ple 13 | ple 14 |
| Etching rate of | 2119 | 1928 | 1956 | 571 | 1583 |
| poly-Si (Å/min) | | | | | |
| Etching rate of | 0.36 | 0.22 | 0.09 | 0.075 | 0.64 |
| SiO₂ (Å/min) | | | | | |
| Etch selectivity ratio | 5886 | 8763 | 21733 | 7613 | 2473 |

TABLE 10

| | Exam- | Exam- | Exam- | Exam- |
|---|---|---|---|---|
| | ple 15 | ple 16 | ple 17 | ple 18 |
| Etching rate of | 1362 | 1639 | 1577 | 2002 |
| poly-Si (Å/min) | | | | |
| Etching rate of | 0.1 | 0.17 | 0.11 | 0.68 |
| SiO₂ (Å/min) | | | | |
| Etch selectivity ratio | 13620 | 9641 | 14336 | 2944 |

TABLE 11

| | Exam- | Exam- | Exam- | Exam- |
|---|---|---|---|---|
| | ple 19 | ple 20 | ple 21 | ple 22 |
| Etching rate of | 2077 | 1354 | 1810 | 1550 |
| poly-Si (Å/min) | | | | |
| Etching rate of | 0.175 | 0.38 | 0.24 | 0.12 |
| SiO₂ (Å/min) | | | | |
| Etch selectivity ratio | 11868 | 3563 | 7541 | 12916 |

TABLE 12

| | Example 23 | Example 24 |
|---|---|---|
| Etching rate of poly-Si (Å/min) | 1904 | 1954 |
| Etching rate of SiO₂ (Å/min) | 0.28 | 0.32 |
| Etch selectivity ratio | 6800 | 6106 |

TABLE 13

| | Example 25 | Example 26 |
|---|---|---|
| Etching rate of poly-Si (Å/min) | 1144 | 194 |
| Etching rate of SiO₂ (Å/min) | 0.18 | 0.075 |
| Etch selectivity ratio | 6355 | 2586 |

From the results shown in Table 7 to Table 13 above, it can be seen that the etching rates of SiO₂ in the compositions of Examples 1-4 and 9-26 are <0.7 Å/min. The etching rates of poly-Si in the compositions of Examples 4, 7-12, 18, 19, 21, and 23-24 are >1800 Å/min. The etch selectivity ratio in the compositions of Examples 1-4, 8-13, and 15-24 are more than 2500. The above results indicate that these compositions can remove a target element at a desired rate while reducing etching the elements other than the target element. Specifically, the compositions of the present disclosure can remove polysilicon at a desired rate without etching silicon oxides. In the method for forming a semiconductor device, when the dummy gate includes polysilicon, the composition of the present disclosure can remove the dummy gate at a good etching rate while maintaining the integrity of the insulation layer and/or spacer, thereby enhancing the electrical properties of the final semiconductor device.

Measurement of Surface Arithmetic Mean Height of Etched Surface

The compositions of Examples 1, 4-9, 11-15, 17, 25 and Comparative Example were heated to 70° C. Polysilicon wafers were immersed in the above compositions for about 30 seconds to 1 minute and silica wafers were immersed in the above compositions for about 120 minutes. The etched surface of the polysilicon wafers etched by compositions of Examples 1, 4-9, 11-15, 17, 25 and Comparative Example were measured by a confocal white light interferometer (Sensofar S-Neox). The surface arithmetic mean height Sa of the etched surface of the polysilicon wafer etched by compositions of Examples 1, 4-9, 11-15, 17, 25 and Comparative Example were calculated by the equation of surface arithmetic mean height mentioned above, and the results are shown in Tables 14 to 16, below.

TABLE 14

| | Example 1 | Example 4 | Example 5 | Example 6 | Example 7 | Example 8 |
|---|---|---|---|---|---|---|
| Sa (nm) | 2 | 4.8 | 1.9 | 2.8 | 2.7 | 3.8 |

TABLE 15

| | Example 9 | Example 11 | Example 12 | Example 13 | Example 14 | Example 15 |
|---|---|---|---|---|---|---|
| Sa (nm) | 2.8 | 1.8 | 2 | 3.7 | 2 | 4.5 |

TABLE 16

| | | | Comparative |
|---|---|---|---|
| | Example 17 | Example 25 | Example |
| Sa (nm) | 1.9 | 6.3 | 34.3 |

As can be seen from the Tables 14 to 16 above, the surface arithmetic mean height Sa of the etched surface of the polysilicon wafer etched by the composition of Comparative Example is 34.3 nm. Compared to the composition of Comparative Example, the surface arithmetic mean height Sa of the etched surface of the polysilicon wafer etched by the composition of Examples 1, 4 to 9, 11 to 15, 17, and 25 is 20 nm or less, and possibly even less than 10 nm. The above results indicate that an etchant with the composition of the present disclosure has a similar etching rate for each crystal surface of polysilicon. The obtained etched surface of the polysilicon element etched by an etchant with the composition of the present disclosure will have an arithmetic mean surface height of 20 nm or less. In the method for forming a semiconductor device, when the dummy gate includes polysilicon, the composition of the present disclosure can reduce residue of the dummy gate, thereby enhancing the electrical properties of the final semiconductor device.

The features of the above embodiments are provided above so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A composition of an etchant, comprising:
0.1 to 13 wt % of quaternary ammonium salts; and
45 to 90 wt % of polar aprotic solvent.

2. The composition of the etchant as claimed in claim 1, wherein the composition of the etchant comprises 2 to 3 wt % of the quaternary ammonium salts.

3. The composition of the etchant as claimed in claim 1, wherein the polar aprotic solvent is sulfolane, dimethyl sulfoxide, or a combination thereof.

4. The composition of the etchant as claimed in claim 1, wherein the composition of the etchant comprises 70 to 75 wt % of the polar aprotic solvent.

5. The composition of the etchant as claimed in claim 1, further comprising 1 to 30 wt % of polar protic solvent.

6. The composition of the etchant as claimed in claim 5, wherein the sum of the polar protic solvent and the polar aprotic solvent accounts for 78 to 85 wt % of the composition of the etchant.

7. The composition of the etchant as claimed in claim 5, wherein the polar protic solvent is a C₂-C₁₀ alkyl alcohol solvent.

8. The composition of the etchant as claimed in claim 5, wherein the polar protic solvent comprises ethylene glycol, 1,2-propanediol, 1,3-propanediol, glycerol, 1,4-butanediol, pentaerythritol, 1,6-hexanediol, di-pentaerythritol, or a combination thereof.

9. The composition of the etchant as claimed in claim 1, further comprising 5 to 11 wt % of polar protic solvent.

10. The composition of the etchant as claimed in claim 9, wherein the polar protic solvent is a C₂-C₁₀ alkyl alcohol solvent.

11. A method for forming a semiconductor device, comprising:
forming an insulation layer over a substrate;
forming a dummy gate over the insulation layer;
forming a spacer on both sides of the dummy gate and the insulation layer;
removing the dummy gate to form a groove; and
forming a metal gate in the groove,
wherein the step of removing the dummy gate comprises using an etchant, a composition of the etchant comprising:
0.1 to 13 wt % of quaternary ammonium salts; and
45 to 90 wt % of polar aprotic solvent.

12. The method for forming a semiconductor device as claimed in claim 11, further comprising forming a high dielectric constant dielectric layer between the metal gate and the spacer.

13. The method for forming a semiconductor device as claimed in claim 12, further comprising removing the insulation layer before the formation of the high dielectric constant dielectric layer.

14. The method for forming a semiconductor device as claimed in claim 11, wherein the composition of the etchant comprises 2 to 3 wt % of the quaternary ammonium salts.

15. The method for forming a semiconductor device as claimed in claim 11, wherein the composition of the etchant comprises 70 to 75 wt % of the polar aprotic solvent.

16. The method for forming a semiconductor device as claimed in claim 11, wherein the composition of the etchant further comprises 1 to 30 wt % of polar protic solvent.

17. The method for forming a semiconductor device as claimed in claim 11, wherein the polar protic solvent is a C₂-C₁₀ alkyl alcohol solvent.

18. A semiconductor device, comprising a polysilicon element having an etched surface, wherein the etched surface is formed by a wet etching process and has a surface arithmetic mean height of 20 nm or less, wherein the wet etching process comprises using an etchant, a composition of the etchant comprising:
0.1 to 13 wt % of quaternary ammonium salts; and
45 to 90 wt % of polar aprotic solvent.

19. The semiconductor device as claimed in claim 18, wherein the composition of the etchant comprises 2 to 3 wt % of the quaternary ammonium salts.

20. The semiconductor device as claimed in claim 18, wherein the composition of the etchant comprises 70 to 75 wt % of the polar aprotic solvent.
